(19) United States
(12) Patent Application Publication
(10) Pub. No.: US 2004/0039868 A1
(43) Pub. Date: Feb. 26, 2004

(54) Facilitating restoration of a system configuration of a data processing system

(76) Inventor: Jeffrey L. Lush, Austin, TX (US)

Correspondence Address: David O. Simmons, SIMON, GALASSO & FRANTZ PLC, P.O. Box 26503, Austin, TX, 78755-0503, US

(21) Appl. No.: 10/224,445

(22) Filed: Aug. 20, 2002

(51) Int. Cl. G11C 5/00

(52) U.S. Cl. 711/4

(57) ABSTRACT

One embodiment of the disclosures made herein is a method for facilitating restoration of a system configuration of a data processing system. In accordance with such embodiment, a hidden recovery partition and an active system configuration partition are created on a first resident storage unit of a data processing system. An image of a baseline system configuration is stored in the hidden recovery partition. A modified system configuration is created and is stored in the active system configuration partition. The modified system configuration is modified with respect to the baseline system configuration. The data processing system is operated in accordance with the modified system configuration. The image of the baseline system configuration is accessed for restoring operation of the data processing system in accordance with the baseline system configuration. Restoring operation of the data processing system in accordance with the baseline system configuration is performed in response to accessing the image of the baseline system configuration and includes replacing the modified system configuration with the baseline system configuration. The method may further include operations for managing data files. In one embodiment of such operations for managing the data files, data files are stored on a second resident storage unit after creating the recovery partition and at least a portion of the second resident storage unit is reformatted in response to restoring operation of the data processing system in accordance with the baseline system configuration. In another embodiment of such operations for managing the data files, a data partition is created on the first resident storage unit in conjunction with creating the hidden recovery partition, data files are stored in the data partition and the data partition is reformatted in response to restoring operation of the data processing system in accordance with the baseline system configuration.

### FIELD OF THE DISCLOSURE

The disclosures made herein relate generally to data processing system and more particularly to facilitating restoration of a system configuration of a data processing system.

### BACKGROUND

Most data processing systems (e.g., laptop computers, desktop computers, personal computers, servers, workstations, and the like) (“DPS”) have a system configuration that specifies various settings that contribute to the functionality capable of being carried out by the DPS. Electronic mail related settings, network related settings, Internet browser related settings, peripheral device related settings, broadband related settings, software related settings and the like are examples of such settings. It is common for a system configuration to include baseline settings (i.e., a baseline system configuration) created, for example, during manufacture of the DPS, during a system migration or during an initial set-up of the DPS. Accordingly, a manufacturer of the DPS, an administrator of the DPS or a user of the DPS may contribute to creating the baseline system configuration.

At some point or points in time after the baseline system configuration is created, one or more actions may be carried out that create a modified system configuration with respect to the baseline system configuration. One example of such an action is that a user of the DPS may intentionally change one or more system configuration settings for the purpose of customizing functionality of the DPS to their preference. Another example of such an action is that the user or system administrator may load a new data processing program (e.g., an application), a new version of an existing data processing program, download information from a network and/or a new peripheral device, thereby causing one or more system configuration settings to be knowingly or unknowingly changed. Creation of the modified system configuration may have an adverse affect on at least a portion of the functionality capable of being carried out by the DPS. For example, certain functionality of the DPS previously capable of being carried out may be inhibited.

Conventional approaches to enabling restoration of a system configuration exhibit one or more limitations. Some limitations associated with conventional approaches for enabling restoration of a system configuration stem from backing-up data as well as an image of the system configuration. Backing up data as well as the image of the system configuration is time consuming and resource intensive. Other limitations associated with conventional approaches for enabling restoration of a system configuration stem from backing up a present system configuration on a consistent (e.g., automated, scheduled) basis. Due to resource limitations, only a limited number of ‘roll-back’ versions of the system configuration can be saved. Accordingly, an initial (e.g., baseline) system configuration is typically overwritten with a present or recently created system configuration. Still other limitations associated with conventional approaches for enabling restoration of a system configuration stem from an attempt to predict when perceived ‘mission critical’ system configuration settings are out-of-specification and need to be restored with known (e.g., preferred, baseline, etc) settings. Such an approach may be inappropriately and unintentionally implemented, thereby restoring system configuration settings that have intentionally been modified. Still other limitations associated with conventional approaches for enabling restoration of a system configuration stem from preventing modification of a ‘pre-configured’ system configuration, precluding personalization and having a potentially adverse affect on productivity of a system user. Yet further limitations associated with conventional approaches for enabling restoration of a system configuration stem from mandating that a baseline or roll-back system configuration be stored remotely from an associated DPS (e.g., at a central server), thus complicating storage of and access to the baseline and/or roll-back system configuration(s).

Therefore, methods and equipment adapted for enabling a baseline system configuration to be captured and selectively restored in a manner that overcomes limitations associated with conventional approaches for facilitating capture and/or restoration of a baseline system configuration would be useful.

### BRIEF DESCRIPTION OF THE DRAWINGS

FIG. 1 depicts a method for facilitating restoration of a system configuration of a DPS in accordance with an embodiment of the disclosures made herein.

FIG. 2 depicts an embodiment of a restoration enablement process in accordance with the method depicted in FIG. 1.

FIG. 3 depicts an embodiment of a system configuration modification process in accordance with the method depicted in FIG. 1.

FIG. 4 depicts an embodiment of a system configuration restoration process in accordance with the method depicted in FIG. 1.

FIG. 5 depicts a method for facilitating restoration of a system configuration of a DPS in accordance with an embodiment of the disclosures made herein.

FIG. 6 depicts an embodiment of a single storage unit DPS in accordance with the disclosures made herein.

FIG. 7 depicts an embodiment of a multiple storage unit DPS in accordance with the disclosures made herein.

### DETAILED DESCRIPTION OF THE DRAWINGS

The disclosures made herein relate to methods and equipment adapted for enabling a baseline system configuration to be captured and selectively restored in a manner that overcomes one or more of the limitations associated with conventional approaches for facilitating capture and/or restoration of a system configuration. Embodiments of system configuration restoration functionality in accordance with the disclosures made herein enable a baseline system configuration to be restored in a timely, reliable, selective and controlled manner. Examples of the baseline system configuration include a factory loaded system configuration, a system configuration generated by a system user and a system configuration generated by a system administrator.

Quite often, a user or administrator of a DPS (e.g., a laptop computer, desktop computer, server, workstation, etc.) initiates an operation that causes modification to a baseline system configuration, thus creating a modified system configuration with respect to the baseline system configuration. Accordingly, the DPS operates or attempts to operate in accordance with the modified system configuration (also known or referred to as the active system configuration). For example, the user or administrator of the DPS may load a new application, download a new application from a public network or install a new hardware component resulting in creation of the modified system configuration. The modified system configuration may result in expected operation of the DPS or may adversely impact operation of the DPS.

In the case where the modified system configuration results in expected operation of the DPS, embodiments of system configuration restoration functionality in accordance with the disclosures made herein allow the user and/or administrator to facilitate using the modified system configuration as the baseline system configuration for the purpose of enabling system configuration restoration (i.e., capturing and storing an image of the system configuration). In the case where the modified system configuration adversely affects operation of the DPS, embodiments of system configuration restoration functionality in accordance with the disclosures made herein allow the user and/or administrator to restore operation of the DPS in accordance with the baseline system configuration. As creating a particular system configuration in a data processing is often a time-consuming, costly and complex process, it is advantageous to be able to restore a retained baseline system configuration in a timely, reliable, selective and controlled manner, such as in the case where a modified system configuration adversely impacts operation of the DPS. Accordingly, the system configuration restoration functionality disclosed herein is a useful and valuable tool for a system user and/or system administrator.

One embodiment of the disclosures made herein is a method for facilitating restoration of a system configuration of a DPS. In accordance with such embodiment, a hidden recovery partition and an active system configuration partition are created on a first resident storage unit of a DPS. An image of a baseline system configuration is stored in the hidden recovery partition. A modified system configuration is created and is stored in the active system configuration partition. The modified system configuration is modified with respect to the baseline system configuration. The DPS is operated in accordance with the modified system configuration. The image of the baseline system configuration is accessed for restoring operation of the DPS in accordance with the baseline system configuration. Restoring operation of the DPS in accordance with the baseline system configuration is performed in response to accessing the image of the baseline system configuration and includes replacing the modified system configuration with the baseline system configuration.

The method may further include operations for managing data files. In one embodiment of such operations for managing the data files, data files are stored on a second resident storage unit after creating the recovery partition and at least a portion of the second resident storage unit is reformatted in response to restoring operation of the DPS in accordance with the baseline system configuration. In another embodiment of such operations for managing the data files, a data partition is created on the first resident storage unit in conjunction with creating the hidden recovery partition, data files are stored in the data partition and the data partition is reformatted in response to restoring operation of the DPS in accordance with the baseline system configuration.

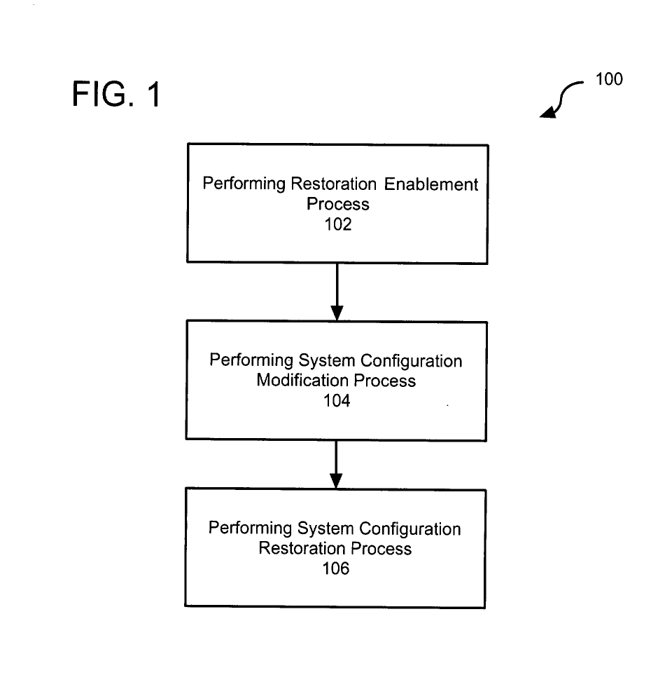

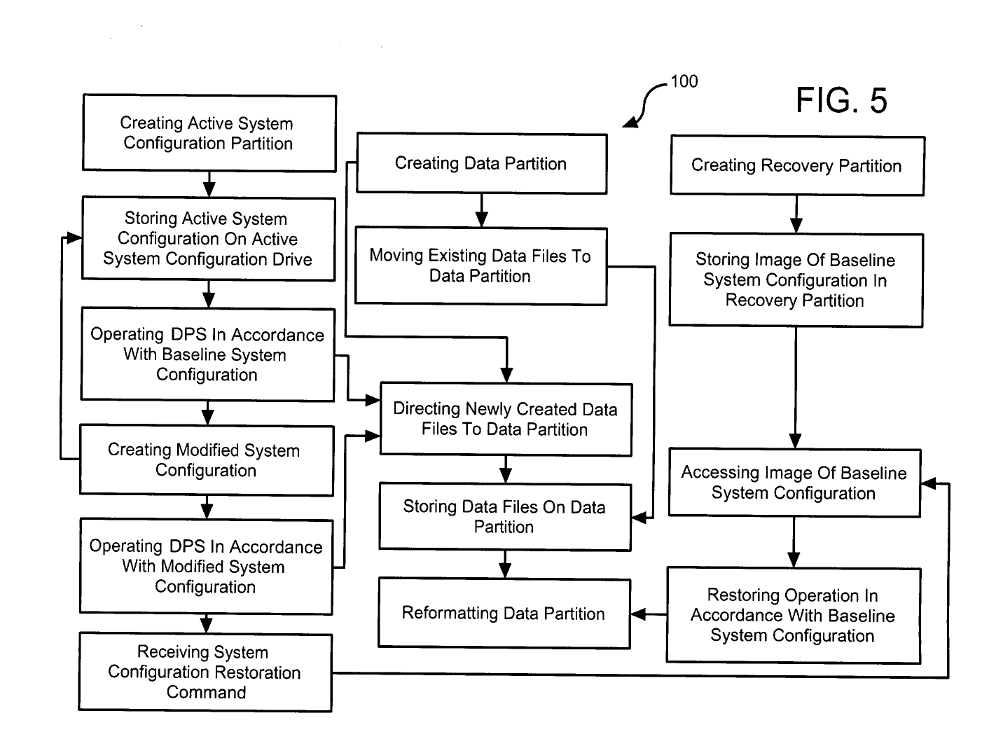

Turning now to specific drawing figures, a method 100 for facilitating restoration of a system configuration of a DPS in accordance with the disclosures made herein is depicted in FIGS. 1 through 5. FIGS. 1 through 4 depict the method 100 from the perspective of an embodiment of processes adapted for facilitating restoration of the system configuration in accordance with the disclosures made herein. FIG. 5 depicts the method 100 from the perspective of an embodiment of operations adapted for facilitating restoration of the system configuration in accordance with the disclosures made herein.

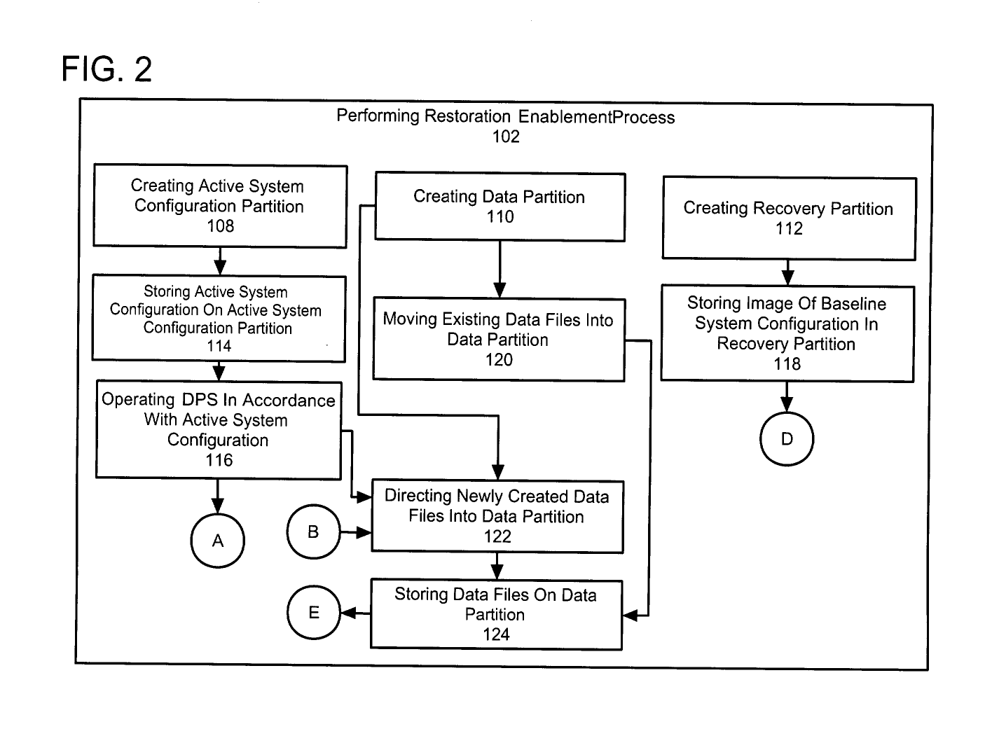

As depicted in FIGS. 1 through 4, the method 100 begins with a restoration enablement process 102 (FIG. 2) being performed. After performing the restoration enablement process 102, a system configuration modification process 104 is performed. Following the restoration enablement process 104 being performed, a system configuration restoration process 106 is performed. Through such processes, and their associated operations, system configuration restoration functionality in accordance with the disclosures made herein is capable of being carried out.

Referring now to FIGS. 2 and 5, the restoration enablement process 102 and, accordingly, the method 100, include an operation 108 performed for creating an active system configuration partition, an operation 110 performed for creating a data partition and an operation 112 performed for creating a recovery partition in a resident storage unit of a DPS. In at least one embodiment of creating the recovery partition, the recovery partition is configured to be a hidden partition. In this manner, the recovery partition is not readily viewable. In at least one embodiment of creating the active system configuration partition and creating the data partition, the active system configuration partition and the data partition are configured as a bootable device drive and an accessible data drive, respectively. For example, the active system configuration partition drive and the data partition are represented as C:/ drive and D:/ drive, respectively.

After creating the active system configuration partition, an operation 114 is performed for storing an active system configuration in the active system configuration partition. After storing the active system configuration in the active system configuration partition, an operation 116 (or process of operations) is performed for operating the DPS in accordance with the active system configuration. A factory loaded system configuration, a system configuration generated by a system user and a system configuration generated by a system administrator are examples of the active system configuration. For example, a system administrator (defined herein to include a system integrator/installer) and/or a system user may create a prescribed system configuration (e.g., in accordance with an installation specification) or a may create customized system configuration. Such a customized system configuration may be a system configuration designated at initial startup of the DPS (e.g., a customized start-up system configuration) or a system configuration that is modified with respect to a factory-loaded system configuration or a prescribed system configuration.

During operation of the DPS in accordance with the active system configuration, an operation 118 is performed for storing an image (e.g., a complete copy) of a baseline system configuration in the recovery partition. At least one embodiment of the operation for storing the image of the baseline system configuration includes capturing the image of the baseline system configuration. For example, an operation for capturing the baseline system configuration is performed in response to receiving a capture image command, wherein the capture image command is transmitted in response to a corresponding menu option being selected. The baseline system configuration is defined herein to be the active system configuration under which the DPS is operating at the point in time when the operation for storing the image is initiated. Accordingly, as discussed herein below in greater detail, the image of the baseline system configuration may be used for enabling the baseline system configuration to be restored as the active system configuration.

An operation 120 is performed after creating the data partition for moving existing data files, if any exist, into the data partition and an operation 122 is performed during operation of the DPS for directing data files (i.e. newly created data files with respect to creating the data partition) into the data partition. Accordingly, an operation 124 is performed for causing such existing data files and/or newly created data files to be stored on the resident storage unit in the data partition. Data files are defined herein to include files that do not comprise the system configuration. The benefit of creating the data partition, moving any existing files into the data partition and directing newly created data files to the data partition is that such data files are not damaged or destroyed in the event that restoration of the baseline system configuration is implemented.

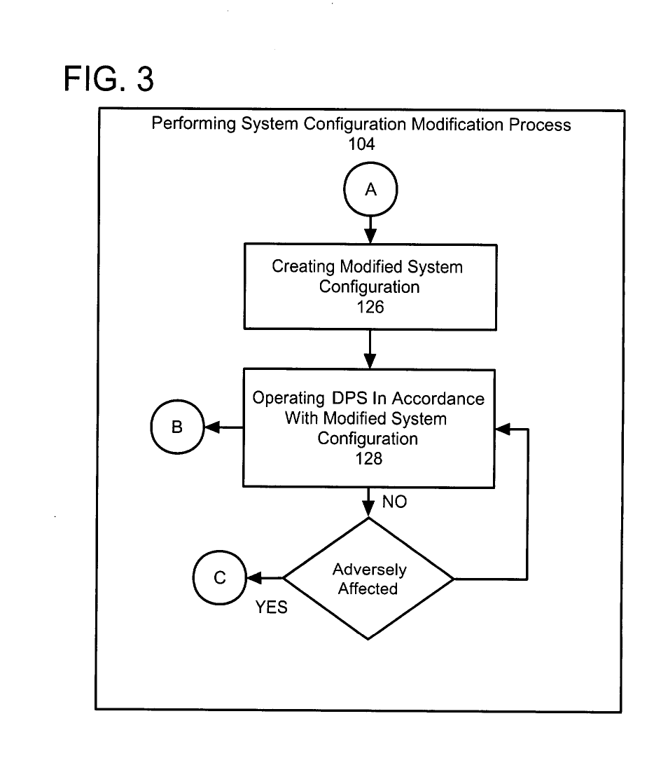

As depicted in FIG. 3 and FIG. 5, an operation 126 is performed for creating a modified system configuration. The operation for creating the modified system configuration may include implementing an explicit command for modifying one or more aspects of the active system configuration (e.g., changing a driver setting) and/or implementing an indirect operation (e.g., loading a new application or adding a new hardware component) that results in associated modification to the active system configuration. Following the modified system configuration being created, an operation 128 (or process of operations) is performed for operating the DPS in accordance with the modified system configuration.

In response to operation of the DPS in accordance with the modified system configuration being performed acceptably, the DPS continues to operate in accordance with the modified system configuration and any newly created data files intended to be stored on the resident storage unit of the DPS continue to be directed to and stored in the data partition. The operation for creating a modified system configuration and the operation for operating the DPS in accordance with the modified system configuration represent an embodiment of the system configuration modification process 104.

If and when operation of the DPS in accordance with the modified system configuration is performed unacceptably, system configuration restoration may be initiated by causing a system configuration restoration command to be issued. For example, upon attempting to run a program that a system user previously ran, the system user becomes aware that modified system configuration is adversely affecting operation of that particular program. Therefore, the system user or system administrator causes the system configuration restoration command to be issued by manually selecting (i.e., being manually issued) an appropriate menu option accessible via the DPS or equivalent method.

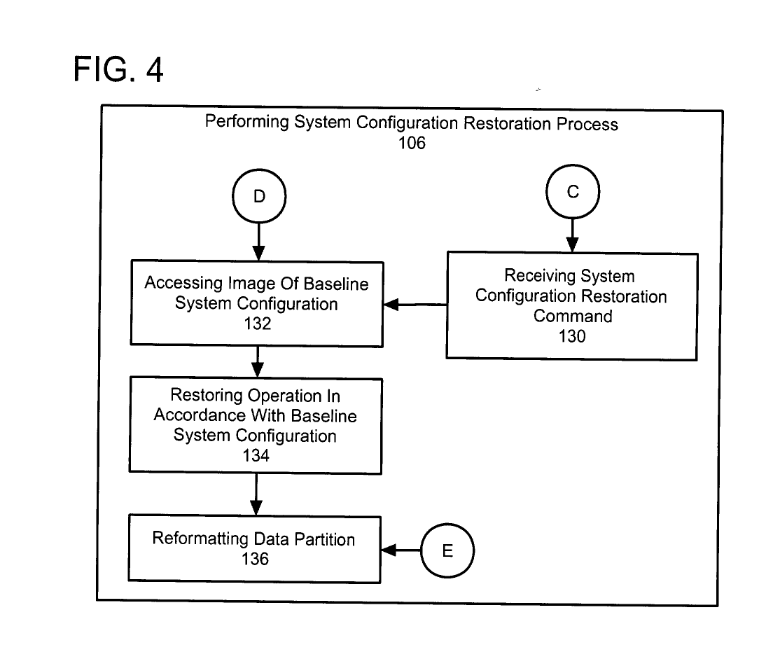

Accordingly, as depicted in FIG. 4 and FIG. 5, an operation 130 is performed for receiving the system configuration restoration command in response to the system configuration restoration command being issued. After receiving the system configuration restoration command and after the baseline image is stored in the recovery partition, an operation 132 is performed for accessing the image of the baseline system configuration from the data partition. In at least one embodiment of the operation for storing the baseline system configuration, an authentication code (e.g., a password, user identification, etc.) is associated with the baseline system configuration (e.g., during the operation of storing the image of the baseline system configuration). Correspondingly, in at least one embodiment of the operation 132 for accessing the image of the baseline system configuration, it is required that the authentication code be received by the DPS prior to performing the operation of accessing the image of the baseline system configuration.

An operation 134 for restoring operation of the DPS in accordance with the baseline system configuration is performed in response to accessing the image of the baseline system configuration. Restoring operation of the DPS in accordance with the baseline system configuration includes replacing the present active system configuration (i.e., the modified system configuration) with the baseline system configuration. When a ‘Full Restoration’ is implemented, an operation 136 for reformatting the data partition is performed in conjunction with restoring operation of the DPS in accordance with the baseline system configuration. When an ‘Image Restoration’ is implemented, the operation for reformatting the data partition is omitted.

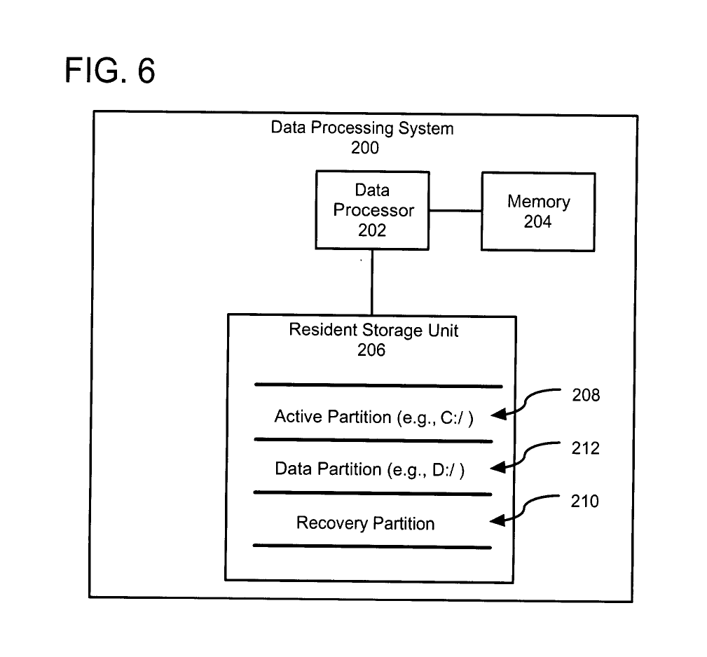

FIG. 6 depicts an embodiment of a single storage unit DPS 200 in accordance with the disclosures made herein. The single storage unit DPS 200 includes a data processor 202, memory 204, and a resident storage unit 206. A hard drive unit is an example of the resident storage unit 206 and the resident storage unit 206 is an example of storage means. The data processor 202 is connected to the memory 204 and to the resident storage unit 206. Accordingly, information (e.g., data, instructions, etc) may be accessible by the data processor 202 from the memory 204 and/or the resident storage unit 206. The resident storage unit 206 is configured to include an active partition 208, a recovery partition 210, and a data partition 212.

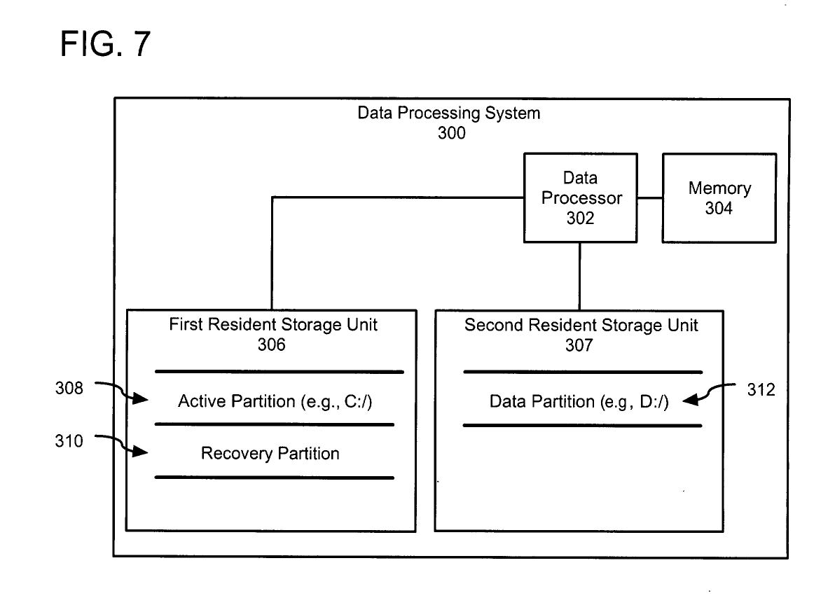

FIG. 7 depicts an embodiment of a multiple storage unit DPS 300 in accordance with the disclosures made herein. The multiple storage unit DPS 300 includes a data processor 302, memory 304, a first resident storage unit 306 and a second resident storage unit 307. A first hard drive unit and a second hard drive unit are examples of the first resident storage unit 306 and the second resident storage unit 307, respectively. The first resident storage unit 306 and the second resident storage unit 307 are an example of storage means. The data processor 302 is connected to the memory 304, to the first resident storage unit 306 and to the second resident storage unit 307. Accordingly, information (e.g., data, instructions, etc) may be accessible by the data processor 302 from the memory 304, the first resident storage unit 306 and/or the second resident storage unit 307. The first resident storage unit 306 is configured to include an active partition 308 and a recovery partition 310. The second storage unit 307 is configured to include a data partition 312.

In at least one embodiment of a DPS in accordance with the disclosures made herein, the DPS includes a data processors and a data processing program for carrying out at least a portion of the system configuration restoration functionality. To this end, the data processor program controls at least a portion of the methods, processes and operations associated with facilitating system configuration restoration functionality. A software program developed by Altiris, Incorporated of 588 West 400 South, Lindon, Utah 84042 (telephone (801)-226-8500) in accordance with a functional specification provided to Altiris by the assignee of this patent application, having a working name of Rapid Image Restore, incorporates portions of the disclosure made herein for enabling at least a portion of the system configuration restoration functionality disclosed herein to be carried out.

The data processor program may be resident on one or more data processing modules (e.g. a card including the data processor) or may be accessible by the data processor from an apparatus such as a diskette, a compact disk, a network storage device, a component of the communication system or other suitable apparatus. The term data processor program is defined herein to refer to computer software, data processor algorithms or any other type of instruction code capable of controlling operations associated with a data processor. A data processor program accessible from an apparatus by a data processor is defined herein as a data processor program product.

In the preceding detailed description, reference has been made to the accompanying drawings that form a part hereof, and in which are shown by way of illustration specific embodiments in which the invention may be practiced. These embodiments, and certain variants thereof, have been described in sufficient detail to enable those skilled in the art to practice the invention. It is to be understood that other suitable embodiments may be utilized and that logical, mechanical, chemical and electrical changes may be made without departing from the spirit or scope of the invention. For example, functional blocks shown in the figures could be further combined or divided in any manner without departing from the spirit or scope of the invention. To avoid unnecessary detail, the description omits certain information know to those skilled in the art. The preceding detailed description is, therefore, not intended to be limited to the specific forms set forth herein, but on the contrary, it is intended to cover such alternatives, modifications, and equivalents, as can be reasonably included within the spirit and scope of the appended claims.

What is claimed is:

1. A method for facilitating restoration of a system configuration of a data processing system, comprising:
creating a recovery partition on a first resident storage unit of a data processing system;
storing an image of a baseline system configuration in the recovery partition; and
accessing the image of the baseline system configuration for restoring operation of the data processing system in accordance with the baseline system configuration.

2. The method of claim 1 wherein creating the recovery partition includes configuring the recovery partition as a hidden partition.

3. The method of claim 1, further comprising:
creating an active system configuration partition on the first resident storage unit in conjunction with creating the recovery partition; and
storing an active system configuration in the active system configuration partition.

4. The method of claim 3 wherein the active system configuration is a modified system configuration with respect to the baseline system configuration.

5. The method of claim 3, further comprising:
creating a data partition on the first resident storage unit in conjunction with creating the recovery partition.

6. The method of claim 5 wherein:
creating the active system configuration partition includes configuring the active system configuration partition as a bootable device drive; and
creating the data partition includes configuring the data partition as a data drive.

7. The method of claim 5, further comprising:
directing newly created data files for being stored on the first resident storage unit in the data partition after creating the recovery partition.

8. The method of claim 7, further comprising;
initiation moving existing data files on the first resident storage unit into the data partition prior to creating said newly created data files.

9. The method of claim 1, further comprising:
creating an active system configuration partition on the first resident storage unit in conjunction with creating the recovery partition;
storing an active system configuration in the active system configuration partition;
directing newly created data files for being stored on a second resident storage unit after creating the recovery partition; and
initiating moving existing data files on the first resident storage unit to the second resident storage unit after creating the recovery partition.

10. The method of claim 1 wherein storing the image of the baseline system configuration includes storing one of an image of a pre-defined system configuration, an image of a user-generated system configuration and an image of an administrator-generated system configuration.

11. The method of claim 1 wherein:
storing the image of the baseline system configuration includes associating an authentication code with the image; and
accessing the image of the baseline system configuration by an accessing party is performed after receiving the authentication code from the accessing party.

12. The method of claim 1 wherein:
storing the image of the baseline system configuration includes capturing the image of the baseline system configuration in response to receiving a capture image command; and
the capture image command is transmitted in response to a corresponding menu option being selected.

13. The method of claim 12 wherein the capture image command is manually issued by one of a data processing system user and a data processing system administrator.

14. The method of claim 1 wherein accessing the image is performed after at least one of creating a modified system configuration and operating the data processing system in accordance with the modified system configuration.

15. The method of claim 1, further comprising;
restoring operation of the data processing system in accordance with the baseline system configuration in response to accessing the image of the baseline system configuration.

16. The method of claim 15 wherein restoring operation includes replacing a modified system configuration with the baseline system configuration.

17. The method of claim 16 wherein the modified system configuration is stored in an active system configuration partition of the first resident storage unit.

18. The method of claim 15, further comprising:
creating a data partition on the first resident storage unit in conjunction with creating the recovery partition;
facilitating storage of data files in the data partition after creating the recovery partition and
reformatting the data partition in response to restoring operation of the data processing system in accordance with the baseline system configuration.

19. The method of claim 15, further comprising:
facilitating storage of data files on a second resident storage unit after creating the recovery partition; and
reformatting at least a portion of the second resident storage unit in response to restoring operation of the data processing system in accordance with the baseline system configuration.

20. A method for facilitating restoration of a system configuration of a data processing system, comprising:
creating a hidden recovery partition and an active system configuration partition on a first resident storage unit of a data processing system;
storing an image of a baseline system configuration in the hidden recovery partition;
creating a modified system configuration, wherein the modified system configuration is modified with respect to the baseline system configuration and wherein the modified system configuration is stored in the active system configuration partition;
operating the data processing system in accordance with the modified system configuration;
accessing the image of the baseline system configuration for restoring operation of the data processing system in accordance with the baseline system configuration; and
restoring operation of the data processing system in accordance with the baseline system configuration in response to accessing the image of the baseline system configuration, wherein restoring operation includes replacing the modified system configuration with the baseline system configuration.

21. The method of claim 20, further comprising:
facilitating storage of data files on a second resident storage unit after creating the recovery partition; and
reformatting at least a portion of the second resident storage unit in response to restoring operation of the data processing system in accordance with the baseline system configuration.

22. The method of claim 20, further comprising:
creating a data partition on the first resident storage unit in conjunction with creating the hidden recovery partition;
facilitating storage of data files in the data partition after creating the recovery partition; and
reformatting the data partition in response to restoring operation of the data processing system in accordance with the baseline system configuration.

23. The method of claim 20, further comprising:
directing newly created data files for being stored on a second resident storage unit after creating the hidden recovery partition; and
initiating moving existing data files on the first resident storage unit to the second resident storage unit after creating the hidden recovery partition.

24. A method for facilitating restoration of a system configuration of a data processing system, comprising:
performing a restoration enablement process for enabling implementation of a system configuration restoration process, wherein the restoration enablement process includes creating a recovery partition on a resident storage unit of the data processing system and storing an image of a baseline system configuration in the recovery partition;
performing a system configuration modification process resulting in operation of the data processing system in accordance with a modified system configuration; and
performing the system configuration restoration process after performing the system configuration modification process, wherein the system configuration restoration process includes accessing the image of the baseline system configuration for enabling operation of the data processing system in accordance with the baseline system configuration.

25. The method of claim 24 wherein:
the restoration enablement process further includes:
creating an active system configuration partition on the first resident storage unit in conjunction with creating the recovery partition; and
storing an active system configuration in the active system configuration partition; and
the active system configuration is a modified system configuration with respect to the baseline system configuration.

26. The method of claim 25 wherein:
the restoration enablement process further includes:
creating a data partition on the first resident storage unit in conjunction with creating the recovery partition.

27. The method of claim 26, further comprising:
directing newly created data files for being stored on the first resident storage unit in the data partition after creating the recovery partition.

28. The method of claim 27, further comprising:
initiating moving existing data files on the first resident storage unit into the data partition prior to creating said newly created data files.

29. The method of claim 24 wherein the restoration enablement process further includes:
creating an active system configuration partition on the first resident storage unit in conjunction with creating the recovery partition;
storing an active system configuration in the active system configuration partition.
directing newly created data files for being stored on a second resident storage unit after creating the recovery partition; and
initiating moving existing data files on the first resident storage unit to the second resident storage unit after creating the recovery partition.

30. The method of claim 24 wherein the system configuration restoration process further includes restoring operation of the data processing system in accordance with the baseline system configuration in response to accessing the image of the baseline system configuration.

31. The method of claim 30 wherein restoring operation includes replacing a modified system configuration with the baseline system configuration.

32. The method of claim 31 wherein the modified system configuration is stored in an active system configuration partition of the first resident storage unit.

33. The method of claim 24 wherein:
the restoration enablement process further includes creating a data partition on the first resident storage unit in conjunction with creating the recovery partition and facilitating storage of data files in the data partition; and
the system configuration restoration process further includes reformatting the data partition in response to restoring operation of the data processing system in accordance with the baseline system configuration.

34. The method of claim 24 wherein:
the restoration enablement process further includes facilitating storage of data files on a second resident storage unit after creating the recovery partition; and
the system configuration restoration process further includes reformatting at least a portion of the second resident storage unit in response to restoring operation of the data processing system in accordance with the baseline system configuration.

35. A data processing system, comprising:
resident storage means having a modified system configuration accessible thereform;
a data processor coupled to said resident storage means;
memory coupled to the data processor; and
a data processor program adapted for enabling the data processor to facilitate:
creating a recovery partition on said resident storage means;
storing an image of a baseline system configuration in the recovery partition; and
accessing the image of the baseline system configuration for enabling operation of the data processor in accordance with the baseline system configuration.

36. The data processing system of claim 35 wherein enabling the data processor to facilitate creating the recovery partition includes enabling the data processor to facilitate configuring the recovery partition as a hidden partition.

37. The data processing system of claim 35 wherein:
the data processing program is further adapted for enabling the data processor to facilitate:
creating an active system configuration partition on the first resident storage unit in conjunction with creating the recovery partition; and
storing an active system configuration in the active system configuration partition; and
the active system configuration is a modified system configuration with respect to the baseline system configuration.

38. The data processing system of claim 37 wherein the data processor program is further adapted for enabling the data processor to facilitate:
creating a data partition on the first resident storage unit in conjunction with creating the recovery partition.

39. The data processing system of claim 38 wherein:
enabling the data processor to facilitate creating the active system configuration partition includes enabling the data processor to facilitate configuring the active system configuration partition as a bootable device drive; and
enabling the data processor to facilitate creating the data partition includes enabling the data processor to facilitate configuring the data partition as a data drive.

40. The data processing system of claim 38 wherein the data processor program is further adapted for enabling the data processor to facilitate directing newly created data files for being stored on the first resident storage unit in the data partition after creating the recovery partition.

41. The data processing system of claim 40 wherein the data processor program is further adapted for enabling the data processor to facilitate initiating moving existing data files on the first resident storage unit into the data partition prior to creating said newly created data files.

42. The data processing system of claim 35 wherein the data processor program is further adapted for enabling the data processor to facilitate:
creating an active system configuration partition on the first resident storage unit in conjunction with creating the recovery partition;
storing an active system configuration in the active system configuration partition;
directing newly created data files for being stored on a second resident storage unit after creating the recovery partition; and
initiating moving existing data files on the first resident storage unit to the second resident storage unit after creating the recovery partition.

43. The data processing system of claim 35 wherein enabling the data processor to facilitate storing the image of the baseline system configuration includes enabling the data processor to facilitate storing one of an image of a pre-defined system configuration, an image of a user-generated system configuration and an image of an administrator-generated system configuration.

44. The data processing system of claim 35 wherein:
enabling the data processor to facilitate storing the image of the baseline system configuration includes enabling the data processor to facilitate associating an authentication code with the image; and
accessing the image of the baseline system configuration by an accessing party is performed after receiving the authentication code from the accessing party.

45. The data processing system of claim 35 wherein:
enabling the data processor to facilitate storing the image of the baseline system configuration includes enabling the data processor to facilitate capturing the image of the baseline system configuration in response to receiving a capture image command; and
the capture image command is transmitted in response to a corresponding menu option being selected.

46. The data processing system of claim 45 wherein the capture image command is manually issued by one of a data processing system user and a data processing system administrator.

47. The data processing system of claim 35 wherein accessing the image is performed after at least one of creating a modified system configuration and operating the data processor in accordance with the modified system configuration.

48. The data processing system of claim 35 wherein the data processor program is further adapted for enabling the data processor to facilitate:
restoring operation of the data processor in accordance with the baseline system configuration in response to accessing the image of the baseline system configuration.

49. The data processing system of claim 48 wherein enabling the data processor to facilitate restoring operation includes enabling the data processor to facilitate replacing a modified system configuration with the baseline system configuration.

50. The data processing system of claim 49 wherein the modified system configuration is stored in an active system configuration partition of the first resident storage unit.

51. The data processing system of claim 48 wherein the data processor program is further adapted for enabling the data processor to facilitate:
creating a data partition on the first resident storage unit in conjunction with creating the recovery partition;
facilitating storage of data files in the data partition; and
reformatting the data partition in response to restoring operation of the data processor in accordance with the baseline system configuration.

52. The data processing system of claim 48 wherein the data processor program is further adapted for enabling the data processor to facilitate:
facilitating storage of data files on a second resident storage unit after creating the recovery partition; and
reformatting at least a portion of the second resident storage unit in response to restoring operation of the data processor in accordance with the baseline system configuration.

53. A data processing system, comprising:
resident storage means having a modified system configuration stored thereon;
a data processor coupled to said resident storage means memory coupled to the data processor; and
a data processor program adapted for enabling the data processor to facilitate:
creating a hidden recovery partition and an active system configuration partition on said resident storage means;
storing an image of a baseline system configuration in the hidden recovery partition;
creating a modified system configuration, wherein the modified system configuration is modified with respect to the baseline system configuration and wherein the modified system configuration is stored in the active system configuration partition;
operating the data processor in accordance with the modified system configuration;
accessing the image of the baseline system configuration for restoring operation of the data processor in accordance with the baseline system configuration; and
restoring operation of the data processor in accordance with the baseline system configuration in response to accessing the image of the baseline system configuration, wherein restoring operation includes replacing the modified system configuration with the baseline system configuration.

54. A data processor program product, comprising:
a data processor program processable by a data processor;
an apparatus from which the data processor program is accessible by the data processor; and
the data processor program being adapted for enabling the data processor to facilitate:
creating a recovery partition on a resident storage unit of a data processing system;
storing an image of a baseline system configuration in the recovery partition; and
accessing the image of the baseline system configuration for enabling operation of the data processing system in accordance with the baseline system configuration.

55. The data processor program product of claim 54 wherein enabling the data processor to facilitate creating the recovery partition includes enabling the data processor to facilitate configuring the recovery partition as a hidden partition.

56. The data processor program product of claim 54 wherein:
the data processing program is further adapted for enabling the data processor to facilitate:
creating an active system configuration partition on the first resident storage unit in conjunction with creating the recovery partition; and
storing an active system configuration in the active system configuration partition; and
the active system configuration is a modified system configuration with respect to the baseline system configuration.

57. The data processor program product of claim 56 wherein the data processor program is further adapted for enabling the data processor to facilitate:
creating a data partition on the first resident storage unit in conjunction with creating the recovery partition.

58. The data processor program product of claim 57 wherein:
enabling the data processor to facilitate creating the active system configuration partition includes configuring the active system configuration partition as a bootable device drive; and
enabling the data processor to facilitate creating the data partition includes enabling the data processor to facilitate configuring the data partition as a data drive.

59. The data processor program product of claim 57, further comprising:
directing newly created data files for being stored on the first resident storage unit in the data partition after creating the recovery partition.

60. The data processor program product of claim 59, further comprising:
initiating moving existing data files on the first resident storage unit into the data partition prior to creating said newly created data files.

61. The data processor program product of claim 54 wherein the data processor program is further adapted for enabling the data processor to facilitate:
creating an active system configuration partition on the first resident storage unit in conjunction with creating the recovery partition;
storing an active system configuration in the active system configuration partition;
directing newly created data files for being stored on a second resident storage unit after creating the recovery partition; and
initiating moving existing data files on the first resident storage unit to the second resident storage unit after creating the recovery partition.

62. The data processor program product of claim 54 wherein enabling the data processor to facilitate storing the image of the baseline system configuration includes enabling the data processor to facilitate storing one of an image of a predefined system configuration, an image of a user-generated system configuration and an image of an administrator-generated system configuration.

63. The data processor program product of claim 54 wherein:
enabling the data processor to facilitate storing the image of the baseline system configuration includes enabling the data processor to facilitate associating an authentication code with the image; and
accessing the image of the baseline system configuration by an accessing party is performed after receiving the authentication code from the accessing party.

64. The data processor program product of claim 54 wherein:
enabling the data processor to facilitate storing the image of the baseline system configuration includes enabling the data processor to facilitate capturing the image of the baseline system configuration in response to receiving a capture image command; and
the capture image command is transmitted in response to a corresponding menu option being selected.

65. The data processor program product of claim 64 wherein the capture image command is manually issued by one of a data processing system user and a data processing system administrator.

66. The data processor program product of claim 54 wherein accessing the image is performed after at least one of creating a modified system configuration and operating the data processing system in accordance with the modified system configuration.

67. The data processor program product of claim 54 wherein the data processor program is further adapted for enabling the data processor to facilitate:
restoring operation of the data processing system in accordance with the baseline system configuration in response to accessing the image of the baseline system configuration.

68. The data processor program product of claim 67 wherein enabling the data processor to facilitate restoring operation includes enabling the data processor to facilitate replacing a modified system configuration with the baseline system configuration.

69. The data processor program product of claim 68 wherein the modified system configuration is stored in an active system configuration partition of the first resident storage unit.

70. The data processor program product of claim 67 wherein the data processor program is further adapted for enabling the data processor to facilitate:
creating a data partition on the first resident storage unit in conjunction with creating the recovery partition;
facilitating storage of data files in the data partition; and
reformatting the data partition in response to restoring operation of the data processing system in accordance with the baseline system configuration.

71. The data processor program product of claim 67 wherein the data processor program is further adapted for enabling the data processor to facilitate:
facilitating storage of data files on a second resident storage unit after creating the recovery partition; and
reformatting at least a portion of the second resident storage unit in response to restoring operation of the data processing system in accordance with the baseline system configuration.

72. A data processor program product, comprising:
a data processor program processable by a data processor of a data processing system;
an apparatus from which the data processor program is accessible by the data processor; and
the data processor program being adapted for enabling the data processor to facilitate:
creating a hidden recovery partition and an active system configuration partition on a first resident storage unit of the data processing system;
storing an image of a baseline system configuration in the hidden recovery partition;
creating a modified system configuration, wherein the modified system configuration is modified with respect to the baseline system configuration and wherein the modified system configuration is stored in the active system configuration partition;
operating the data processing system in accordance with the modified system configuration;
accessing the image of the baseline system configuration for restoring operation of the data processing system in accordance with the baseline system configuration; and
restoring operation of the data processing system in accordance with the baseline system configuration in response to accessing the image of the baseline system configuration, wherein restoring operation includes replacing the modified system configuration with the baseline system configuration.

73. The method of claim 72 wherein the data processor program is further adapted for enabling the data processor to facilitate:
reformatting at least a portion of the second resident storage unit in response to restoring operation of the data processing system in accordance with the baseline system configuration.

74. The method of claim 72 wherein the data processor program is further adapted for enabling the data processor to facilitate:
creating a data partition on the first resident storage unit in conjunction with creating the hidden recovery partition; and
reformatting the data partition in response to restoring operation of the data processing system in accordance with the baseline system configuration.

75. The method of claim 72 wherein the data processor program is further adapted for enabling the data processor to facilitate:
directing newly created data files for being stored on a second resident storage unit after creating the hidden recovery partition; and
initiating moving existing data files on the first resident storage unit to the second resident storage unit after creating the hidden recovery partition.

76. A data processing system, comprising:
storage means including an active drive having a modified system configuration accessible therefrom, a data drive having data information accessible therefrom and a recovery partition having an image of a baseline system configuration accessible therefrom;
a data processor operating in accordance with the modified system configuration; and
a data processor program adapted for enabling the data processor to facilitate:
performing a system configuration restoration process, wherein the system configuration restoration process includes accessing the image of the baseline system configuration for enabling operation of the data processor in accordance with the baseline system configuration.

77. The data processing system of claim 76 wherein the system configuration restoration process further includes restoring operation of the data processor in accordance with the baseline system configuration in response to accessing the image of the baseline system configuration.

78. The data processing system of claim 77 wherein restoring operation includes replacing the modified system configuration with the baseline system configuration.

79. The data processing system of claim 76 wherein the system configuration restoration process further includes reformatting at least a portion of the data drive in response to restoring operation of the data processor in accordance with the baseline system configuration.

80. A data processor program product, comprising:
a data processor program processable by a data processor of a data processing system;
an apparatus from which the data processor program is accessible by the data processor; and
the data processor program being adapted for enabling the data processor to facilitate:
performing a restoration enablement process for enabling implementation of a system configuration restoration process, wherein the restoration enablement process includes creating a recovery partition on a resident storage unit of the data processing system and storing an image of a baseline system configuration in the recovery partition;
performing a system configuration modification process resulting in operation of the data processing system in accordance with a modified system configuration; and
performing the system configuration restoration process after performing the system configuration modification process, wherein the system configuration restoration process includes accessing the image of the baseline system configuration for enabling operation of the data processing system in accordance with the baseline system configuration.

81. The data processor program product of claim 80 wherein:
the restoration enablement process further includes:
creating an active system configuration partition on the first resident storage unit in conjunction with creating the recovery partition; and
storing an active system configuration in the active system configuration partition; and
the active system configuration is a modified system configuration with respect to the baseline system configuration.

82. The data processor program product of claim 81 wherein:
the restoration enablement process further includes:
creating a data partition on the first resident storage unit in conjunction with creating the recovery partition.

83. The data processor program product of claim 82, further comprising:
directing newly created data files for being stored on the first resident storage unit in the data partition after creating the recovery partition.

84. The data processor program product of claim 83, further comprising:
initiating moving existing data files on the first resident storage unit into the data partition prior to creating said newly created data files.

85. The data processor program product of claim 80 wherein the restoration enablement process further includes:
creating an active system configuration partition on the first resident storage unit in conjunction with creating the recovery partition;
storing the active system configuration in the active system configuration partition;
directing newly created data files for being stored on a second resident storage unit after creating the recovery partition; and
initiating moving existing data files on the first resident storage unit to the second resident storage unit after creating the recovery partition.

86. The data processor program product of claim 80 wherein the system configuration restoration process further includes restoring operation of the data processing system in accordance with the baseline system configuration in response to accessing the image of the baseline system configuration.

87. The data processor program product of claim 86 wherein restoring operation includes replacing a modified system configuration with the baseline system configuration.

88. The data processor program product of claim 87 wherein the modified system configuration is stored in an active system configuration partition of the first resident storage unit.

89. The data processor program product of claim 80 wherein:
the restoration enablement process further includes creating a data partition on the first resident storage unit in conjunction with creating the recovery partition and facilitating storage of data files in the data partition; and
the system configuration restoration process further includes reformatting the data partition in response to restoring operation of the data processing system in accordance with the baseline system configuration.

90. The data processor program product of claim 80 wherein:
the restoration enablement process further includes facilitating storage of data files on a second resident storage unit after creating the recovery partition; and
the system configuration restoration process further includes reformatting at least a portion of the second resident storage unit in response to restoring operation of the data processing system in accordance with the baseline system configuration.
